(19) United States
(12) Patent Application Publication
(10) Pub. No.: US 2025/0067800 A1
(43) Pub. Date: Feb. 27, 2025

(54) TESTING APPARATUS, TESTING METHOD, AND COMPUTER-READABLE STORAGE MEDIUM

(71) Applicant: ADVANTEST CORPORATION, Tokyo (JP)

(72) Inventors: Koji MIYAUCHI, Gunma (JP); Kotaro HASEGAWA, Saitama (JP)

(21) Appl. No.: 18/738,071

(22) Filed: Jun. 10, 2024

(30) Foreign Application Priority Data
Aug. 25, 2023 (JP) 2023-137536

(51) Int. Cl. G01R 31/311

(52) U.S. Cl. CPC G01R 31/311

(57) ABSTRACT

Provided is a testing apparatus including: a light source; an electrical measurement unit which measures a photoelectric signal obtained by a test target light emitting element photoelectrically converting light radiated from the light source; and a calculation unit which calculates pseudo external quantum efficiency having a correlation with inherent external quantum efficiency of the test target light emitting element, based on irradiation intensity of light radiated from the light source to the test target light emitting element, a light emission wavelength relating to light emission of the test target light emitting element, and the photoelectric signal being measured of the test target light emitting element.

### BACKGROUND

### 1. Technical Field

The present invention relates to a testing apparatus, a testing method, and a computer-readable storage medium.

### 2. Related Art

Patent Document 1 describes that “A solar cell was characterized as follows. External quantum efficiency (EQE) was estimated by using cell responses at different wavelengths (measured with a white light halogen lamp in combination with a bandpass filter).” ([0121]).

### CITATION LIST

### Patent Document

Patent Document 1: Japanese Patent Application Publication No. 2021-9950

### BRIEF DESCRIPTION OF THE DRAWINGS

FIG. 1 is an example of a general view showing a schematic of a testing apparatus 100 for testing a plurality of LEDs 10.

FIG. 2 is an example of the general view showing the schematic of the testing apparatus 100 for testing the plurality of LEDs 10.

FIG. 3 is an example of a flow diagram for explaining a flow of a testing method by the testing apparatus 100.

FIG. 4 shows an example of a computer 1200 in which a plurality of aspects of the present invention may be embodied in whole or in part.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

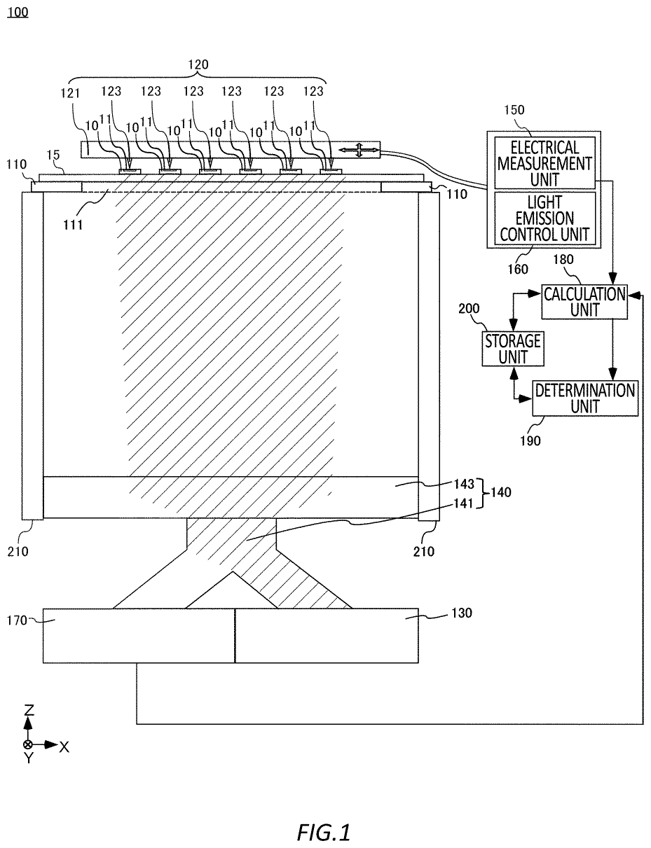

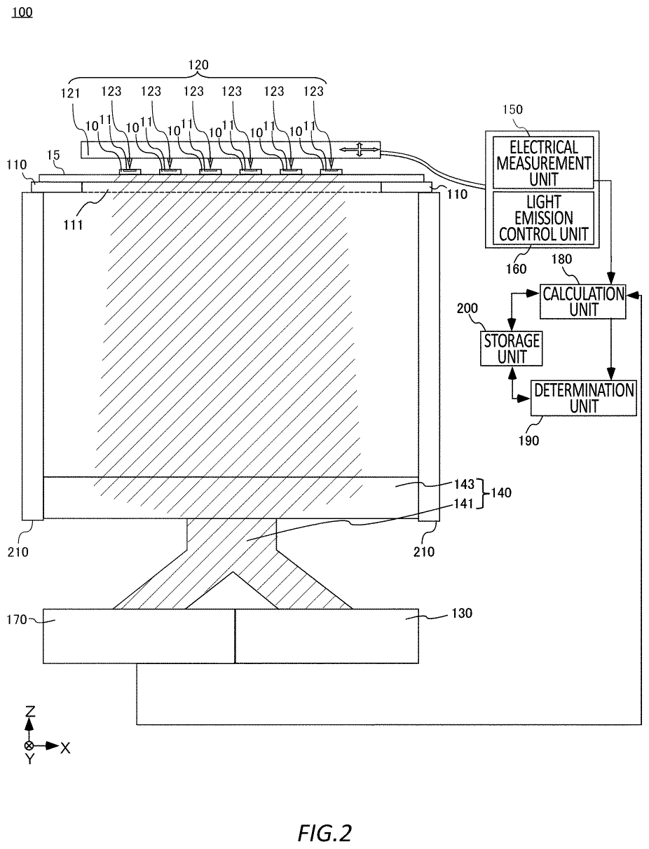

FIGS. 1 and 2 are examples of a general view showing a schematic of a testing apparatus 100 for testing a plurality of LEDs 10. FIGS. 1 and 2 show an X axis, a Y axis, and a Z axis orthogonal to one another. A rightward direction with respect to a paper surface is defined as an X-axis positive direction, an upward direction with respect to the paper surface is defined as a Z-axis positive direction, and a depth direction with respect to the paper surface is defined as a Y-axis positive direction.

Using the photoelectric effect of the light emitting element, the testing apparatus 100 calculates pseudo external quantum efficiency having a correlation with the inherent external quantum efficiency of the light emitting element, based on the photoelectric signal output from the light emitting element irradiated with light. The testing apparatus 100 according to the present embodiment collectively irradiates, with light, on a LED group in which the plurality of LEDs 10 are formed on a wafer 15 that is, for example, an LED wafer, to calculate the pseudo external quantum efficiency of each LED 10 based on the photoelectric signal output from each LED 10. The testing apparatus 100 according to the present embodiment further calculates an estimation value of the inherent external quantum efficiency of each LED 10 from the pseudo external quantum efficiency of each LED 10. The testing apparatus 100 according to the present embodiment tests the optical characteristics of the LED 10 by calculating the external quantum efficiency of the LED 10 in this manner.

In the present embodiment, the LED 10 is a micro LED having a dimension equal to or less than 100 μm. Note that instead of the micro LED, the LED 10 may be a mini LED having a dimension larger than 100 μm and equal to or less than 200 μm, an LED having a dimension larger than 200 μm, or may be another light emitting element such as an LD. These are examples of a test target light emitting element and a reference light emitting element.

In the present embodiment, the plurality of LEDs 10 are not electrically connected to one another on the wafer 15. The LED group is a back surface emission type in which the light emitting surfaces of the plurality of LEDs 10 face the wafer 15, and the wafer 15 transmits light. On each LED 10, two terminals 11 are formed apart from each other in a Y axis direction. Each terminal 11 of the plurality of LEDs 10 does not face the wafer 15. Note that, in the LED group of a back surface emission type as in the present embodiment, the plurality of LEDs 10 and the wafer 15 on which the plurality of LEDs 10 are mounted may be collectively referred to as a wafer. Note that the LED group may be a front surface emission type in which the light emitting surfaces of the plurality of LEDs 10 do not face the wafer 15, and in this case, the wafer 15 may not transmit light, and each terminal 11 of the plurality of LEDs 10 may not face the wafer 15 or may face the wafer 15. When each terminal 11 of the plurality of LEDs 10 faces the wafer 15, a via extending in a Z axis direction may be formed at the position of each terminal 11 in the wafer 15 so as to bring a power supply probe into contact with each terminal 11.

The plurality of LEDs 10 may be formed on a wafer provided with electrical wirings or on a glass-based panel (PLP) having a substantially rectangular outer shape, and may be electrically connected to one another to be unitized or cellularized.

As an example, the testing apparatus 100 according to the present embodiment includes a placement unit 110, an electrical connection unit 120, a light source 130, an optical system 140, an electrical measurement unit 150, a light emission control unit 160, a light measurement unit 170, a calculation unit 180, a determination unit 190, a storage unit 200, and a shielding unit 210. In FIGS. 1 and 2, the flow of signals between the components is indicated by black arrows.

The placement unit 110 has the LED group placed thereon on the Z-axis positive direction side. The placement unit 110 has the LED group including a plurality of test target LEDs 10 placed thereon. Further, the placement unit 110 may have one or more singulated reference LEDs 10 directly placed thereon or may have an LED group including one or more reference LEDs 10 placed thereon.

The placement unit 110 in the shown example has a substantially circular outer shape in a plan view from the Z axis direction, but may have another outer shape. The placement unit 110 has a holding function such as a vacuum chuck, an electrostatic chuck, and the like, and holds the wafer 15 of the placed LED group. The placement unit 110 has a through hole 111 in the central portion of an XY plane so as not to block light that passes through the wafer 15 from the light source 130 and is radiated on the plurality of LEDs 10 or light that is emitted from the plurality of LEDs 10 and passes through the wafer 15, for example. The placement unit 110 holds the wafer 15 around the through hole 111. Note that in FIGS. 1 and 2, the through hole 111 is indicated by a broken line.

The electrical connection unit 120 is, for example, a probe card (probe substrate), and is electrically connected to the terminal 11 of each of the plurality of LEDs 10 included in the LED group to be tested. Further, the electrical connection unit 120 according to the present embodiment is also electrically connected to each terminal 11 of one or more singulated reference LEDs 10 or each terminal 11 of the LED group including one or more reference LEDs 10.

The electrical connection unit 120 includes a substrate 121 and a plurality of probes 123. An electric circuit and a plurality of electrical wirings are provided on the substrate 121. The plurality of probes 123 are provided on one main surface of the substrate 121 and protrude from the one main surface of the substrate 121. Each of the plurality of probes 123 can contact the terminal 11 of each LED 10 in a state where the substrate 121 faces the LED group on the placement unit 110.

The electrical connection unit 120 moves two-dimensionally in an XY plane and moves up and down in the Z axis direction. In FIGS. 1 and 2, the moving direction of the electrical connection unit 120 is indicated by a white arrow. For example, the electrical connection unit 120 moves such that the plurality of LEDs 10 are positioned between the electrical connection unit 120 and the light source 130, and brings the plurality of probes 123 into contact with respective terminals 11 of the plurality of LEDs 10 from the Z-axis positive direction side of the wafer 15. The other end of each probe 123 on the opposite side of one end in contact with the terminal 11 is electrically connected to the electrical wiring provided on the substrate 121. The electrical wiring of each probe 123 extends from the side surface of the substrate 121 and is electrically connected to the electrical measurement unit 150 and the light emission control unit 160.

The light source 130 irradiates one or more LEDs 10 with light. In the present embodiment, as shown in FIG. 1, the light source 130 irradiates one or more LEDs 10 with light via the optical system 140. In FIG. 1, the light emitted from the light source 130 is indicated by hatching.

The light source 130 is, as an example, a white light source or a light source that emits light of a specific wavelength. When the light source 130 that is a white light source is used, a filter that filters light in an infrared region may be arranged between the light source 130 and the LED 10 to prevent the LED 10 from being heated to a high temperature. When the light source 130 that emits light of a specific wavelength is used, the light source 130 may be set to emit light of a reaction wavelength of the LED 10, that is, light of a wavelength at which the LED 10 can output a photoelectric signal. As an example, when the design values of the light emission wavelength and the reaction wavelength of the LED 10 are 446 nm and 560 nm, the light source 130 may be set to emit light in a wavelength range of 560 nm±several nm. When the light source 130 that emits light having the reaction wavelength of the LED 10 is used, energy efficiency can be enhanced as compared with that of the white light source since the light source 130 does not emit light having a wavelength other than the reaction wavelength of the LED 10. In this case, for example, a filter that filters light in an infrared region that is a wavelength range other than the reaction wavelength of the LED 10 can be made unnecessary.

The light source 130 may be a surface light source capable of uniformly irradiating, with light, a plane on which an irradiation target is positioned. In this case, the irradiation intensity ([mW]) of the light radiated from the light source 130 to each of the plurality of LEDs 10 on the placement unit 110 may be calculated in advance by multiplying the irradiation intensity per unit area ([mW/cm²]) of the light emitted from the light source 130 by the area ([cm²]) of each LED 10 and stored in the storage unit 200. Alternatively, the light source 130 may emit light having an illuminance distribution in the plane, and in this case, the illuminance distribution may be measured in advance and stored in the storage unit 200. For example, the irradiation intensity of the light radiated from the light source 130 to each position of the plurality of LEDs 10 on the placement unit 110 may be measured in advance and stored in the storage unit 200, and the irradiation intensity for each position may be applied to the calculation of the external quantum efficiency described above. Note that the irradiation intensity of the light radiated from the light source 130 to each of the plurality of LEDs 10 is intended to be the irradiation intensity of the light having the reaction wavelength of the LED 10 among the light emitted from the light source 130. For example, when the light source 130 is a white light source, the irradiation intensity of the light having the reaction wavelength of the LED 10 can be calculated by multiplying the irradiation intensity of the light emitted from the light source 130 in the entire wavelength range by the ratio of the relative intensity of the reaction wavelength of the LED 10 when the total intensity in the entire wavelength range is 1. Note that the light source 130 may be capable of adjusting the irradiation time, wavelength, intensity, and the like of the light which is radiated on the target.

The optical system 140 irradiates one or more LEDs 10 with light incident from the light source 130. As shown in FIGS. 1 and 2, the optical system 140 according to the present embodiment is arranged such that one side is connected to the light source 130 and the light measurement unit 170 and another side faces the LED group on the placement unit 110. In the present embodiment, the optical system 140 is an optical element group common to the light source 130 and the light measurement unit 170. The optical system 140 enables photoelectric signal measurement and wavelength measurement for the LED 10 by using bidirectional optical paths. Specifically, the optical system 140 irradiates the LED 10 with light incident from the light source 130 in one direction, and irradiates the light measurement unit 170 with light incident from the LED 10 in another direction.

More specifically, as shown in FIG. 1, the optical system 140 according to the present embodiment diffuses the light emitted from the light source 130 to collectively irradiate the plurality of LEDs 10 with the light emitted from the light source 130. That is, the surface onto which the light emitted from the light source 130 via the optical system 140 is projected on the XY plane on the placement unit 110 covers at least the plurality of LEDs 10 of the LED group. The optical system 140 according to the present embodiment also irradiates the light

measurement unit 170 with combined light obtained by combining the light emitted from each of the plurality of LEDs 10. In FIG. 2, the combined light emitted from the plurality of LEDs 10 is indicated by hatching. As shown in FIG. 2, the optical system 140 condenses diffused light emitted from the plurality of LEDs 10 to guide the light to the light measurement unit 170. As shown in FIG. 2, the optical system 140 according to the present embodiment guides the light emitted from the plurality of LEDs 10 to both the light source 130 and the light measurement unit 170, but alternatively, the optical system 140 may be configured to guide the light emitted from the plurality of LEDs 10 only to the light measurement unit 170 and not to the light source 130.

The optical system 140 according to the present embodiment includes a bifurcated fiber 141. The bifurcated fiber 141 is a Y-shaped optical fiber. The end portions of the bifurcated fiber 141 on the branched side are connected to the light source 130 and the light measurement unit 170. The optical system 140 may include a multi-branched fiber such as a three-branched fiber or a four-branched fiber instead of the bifurcated fiber 141. In this case, the testing apparatus 100 may include two or more light sources 130, and one light source 130 may be connected to each end portion of the multi-branched fiber on the branch side. In this case, the optical system 140 may combine light emitted from the plurality of light sources 130 that radiate light in different wavelength bands and irradiate the plurality of LEDs 10 therewith. For example, the optical system 140 may combine light emitted from three light sources 130 that emit light of respective reaction wavelengths of RGB of the LED 10 and irradiate the LED 10 therewith. When the light source 130 emits light of a specific wavelength band, the plurality of light sources 130 are connected to the optical system 140 in this manner, so that the wavelength bandwidth of the light with which the LED 10 is irradiated can be widened, and the LED 10 can be caused to perform photoelectric conversion more reliably.

The optical system 140 may further have a lens unit 143 including one or more lenses, and the lens unit 143 is arranged on an optical path in the optical system 140. In addition, as shown in FIG. 2, the lens unit 143 converges the diffused light emitted from the plurality of LEDs 10 and causes the light to enter the bifurcated fiber 141.

In the testing apparatus 100, the optical system 140, the light source 130, and the light measurement unit 170 are configured to be connected to one another, so that the photoelectric signal measurement and the wavelength measurement for the plurality of LEDs 10 can be performed bidirectionally by using the common optical system 140. When the testing apparatus 100 ends one of the photoelectric signal measurement and the wavelength measurement and starts another, it is not necessary to change an apparatus configuration or move the LED 10.

The electrical measurement unit 150 measures a photoelectric signal obtained by the test target LED 10 photoelectrically converting the light radiated from the light source 130. The electrical measurement unit 150 according to the present embodiment measures a photoelectric signal obtained by each of the plurality of test target LEDs 10 photoelectrically converting the light collectively radiated from the light source 130. The electrical measurement unit 150 according to the present embodiment further measures a photoelectric signal obtained by one or more reference LEDs 10 photoelectrically converting the light radiated from the light source 130.

More specifically, the electrical measurement unit 150 measures a current value of the current output from each LED 10 via the electrical connection unit 120. The electrical measurement unit 150 outputs, to the calculation unit 180, the current value measured for each LED 10. Note that the electrical measurement unit 150 may measure a voltage value corresponding to the current value, instead of the current value of the current output from the LED 10.

The light emission control unit 160 causes the LED 10 to emit light by supplying current or voltage having a predetermined magnitude to the LED 10. The light emission control unit 160 according to the present embodiment supplies current or voltage having a predetermined magnitude via the electrical connection unit 120 to the plurality of test target LEDs 10, thereby causing the plurality of test target LEDs 10 to collectively emit light. The light emission control unit 160 according to the present embodiment further causes one or more reference LEDs 10 to emit light.

The light measurement unit 170 measures the wavelength of the light emitted from the LED 10. The light measurement unit 170 according to the present embodiment measures the wavelength of the combined light received via the optical system 140 and obtained by combining the light emitted from each of the plurality of LEDs 10. The combined light obtained by combining the light emitted from each of the plurality of LEDs 10 is an example of the light emission wavelength relating to the light emission of the plurality of test target LEDs 10. The light measurement unit 170 may measure the wavelengths of the light emitted by one or more LEDs 10 in the group for each group obtained by dividing all the test target LEDs 10 into several groups. In addition, the light measurement unit 170 may individually measure the wavelength of the light emitted from each of the plurality of test target LEDs 10. The light measurement unit 170 according to the present embodiment further measures the wavelength and the light emission intensity of the light emitted from one or more reference LEDs 10.

The light measurement unit 170 according to the present embodiment includes, for example, a wavelength meter. The light measurement unit 170 may measure the wavelength of the combined light emitted from the plurality of LEDs 10 and specify the intensity distribution of the wavelength of the combined light. The light measurement unit 170 may specify the peak wavelength and the half-value width of the combined light based on the intensity distribution of the combined light, and may measure a main wavelength that is a wavelength corresponding to a color when the combined light is viewed with eyes. The light measurement unit 170 may include a spectrometer, an optical spectrum analyzer, or the like instead of the wavelength meter. The light measurement unit 170 outputs the measured wavelength or light emission intensity to the calculation unit 180.

The calculation unit 180 calculates pseudo external quantum efficiency having a correlation with the inherent external quantum efficiency of the test target LED 10. More specifically, the calculation unit 180 calculates the pseudo external quantum efficiency based on the irradiation intensity with which the test target LED 10 is irradiated from the light source 130, the light emission wavelength relating to the light emission of the test target LED 10, and the measured photoelectric signal of the test target LED 10. The calculation unit 180 further calculates an estimation value of the inherent external quantum efficiency, which is obtained from a light emission test, of the test target LED 10 from the pseudo external quantum efficiency of the test target LED 10.

The calculation unit 180 according to the present embodiment calculates the pseudo external quantum efficiency of each of the plurality of test target LEDs 10. More specifically, the calculation unit 180 calculates the pseudo external quantum efficiency of each of the plurality of test target LEDs 10 based on the irradiation intensity with which the plurality of test target LEDs 10 are irradiated from the light source 130, the light emission wavelength relating to the light emission of the plurality of test target LEDs 10, and the photoelectric signal measured for each of the plurality of test target LEDs 10. The calculation unit 180 further calculates an estimation value of the inherent external quantum efficiency, which is obtained from the light emission test, of each of the plurality of test target LEDs 10 from the pseudo external quantum efficiency of the plurality of test target LEDs 10.

The calculation unit 180 may acquire data of the irradiation intensity with which one or more test target LEDs 10 are irradiated from the light source 130, for example, from the outside of the testing apparatus 100 by a user input and store the data in the storage unit 200. Note that the irradiation intensity with which one or more test target LEDs 10 are irradiated from the light source 130 may be measured by placing the light measurement unit 170 instead of the LED group on the placement unit 110 in the testing apparatus 100.

The calculation unit 180 uses, for example, the wavelength of the combined light of the plurality of LEDs 10 input from the light measurement unit 170 as the light emission wavelength relating to the light emission of the plurality of test target LEDs 10. Alternatively, the calculation unit 180 may use the wavelength of the reference LED 10 input from the light measurement unit 170 as the light emission wavelength relating to the light emission of one or more test target LEDs 10.

The reference LED 10 described above may be the LED 10 exhibiting an excellent light emission characteristic that can be compared with the light emission characteristic of the test target LED 10. The reference LED 10 may be, for example, an ideal light emitting element conforming to the design value of the test target LED 10, or may be the LED 10 that satisfies a predetermined acceptance reference and is included in the same production lot as the test target LED 10. The predetermined acceptance reference can be defined, for example, for each user who manufactures and sells the test target LED 10.

The pseudo external quantum efficiency described above is calculated by a derivation formula: EQE=[P/(I×E)]×100, similarly to the generally known inherent external quantum efficiency. However, although the inherent external quantum efficiency is based on the light emission efficiency, the pseudo external quantum efficiency is based on the light reception efficiency, and thus the inherent external quantum efficiency and the pseudo external quantum efficiency have values different from each other. In the derivation formula described above, when deriving the inherent external quantum efficiency, EQE is the inherent external quantum efficiency ([%]), P is the light emission intensity ([mW]) of the element, I is the current value ([mA]) input to the element, and E is the energy of light and is a value ([eV]) obtained by dividing the product (1240 [nm·eV]) of the Planck constant and a light flux in vacuum by the light emission wavelength ([nm]) of the element. When deriving the pseudo external quantum efficiency, EQE is the pseudo external quantum efficiency ([%]), P is the irradiation intensity ([mW]) of the light radiated on the element, I is a current value ([mA]) of the photoelectric signal output from the element, and E is the energy of light and is the value ([eV]) obtained by dividing the product (1240 [nm·eV]) of the Planck constant and the light flux in vacuum by the light emission wavelength ([nm]) of the element.

It is understood that the pseudo external quantum efficiency has a positive correlation with the inherent external quantum efficiency. Therefore, the light emission characteristics of the light emitting element can be evaluated by using the pseudo external quantum efficiency. In addition, for example, by dividing the inherent external quantum efficiency of a specific light emitting element by the pseudo external quantum efficiency of the light emitting element, a correlation coefficient of the light emitting element can be obtained. The correlation coefficient between the pseudo external quantum efficiency and the inherent external quantum efficiency of the light emitting element may be different for each design value of the light emitting element, that is, may be different for each production lot of the light emitting element.

In this regard, the calculation unit 180 according to the present embodiment uses a correction coefficient calculated in advance as the correlation coefficient corresponding to the test target LED 10 to calculate the estimation value of the inherent external quantum efficiency, which is obtained from the light emission test, of the test target LED 10 from the pseudo external quantum efficiency of the test target LED 10. The calculation unit 180 uses the correction coefficient varying depending on a production lot including one or more test target LEDs 10. Note that the plurality of LEDs 10 formed on the same wafer 15 are LEDs 10 produced based on the same design value, and are LEDs 10 included in the same production lot. The calculation unit 180 outputs the estimation value of the inherent external quantum efficiency to the determination unit 190.

The determination unit 190 determines the quality of each of the plurality of test target LEDs 10 based on the estimation value of the inherent external quantum efficiency of each of the plurality of test target LEDs 10. For example, the determination unit 190 may determine the quality of each of the plurality of test target LEDs 10 by comparison with the inherent external quantum efficiency of the reference LED 10 stored in the storage unit 200, that is, by comparison with a threshold to be a predetermined acceptance reference. For example, the determination unit 190 may specify the LED 10 of which the inherent external quantum efficiency is an outlier, based on the statistical value of the inherent external quantum efficiency of the plurality of test target LEDs 10, and determine the LED 10 as defective. Further, the determination unit 190 may exclude, from the targets of the subsequent test, the LED 10 determined to have defective inherent external quantum efficiency.

The shielding unit 210 shields light other than the light emitted from the light source 130 and the LED 10. The surface of the shielding unit 210 in the present embodiment is entirely painted black to prevent irregular reflection of light on the surface. In addition, as shown in FIG. 1, the shielding unit 210 is provided so as to form a sealed space by the lens unit 143, the placement unit 110, and the wafer 15, and this configuration shields light other than the light emitted from the light source 130 and the LED 10.

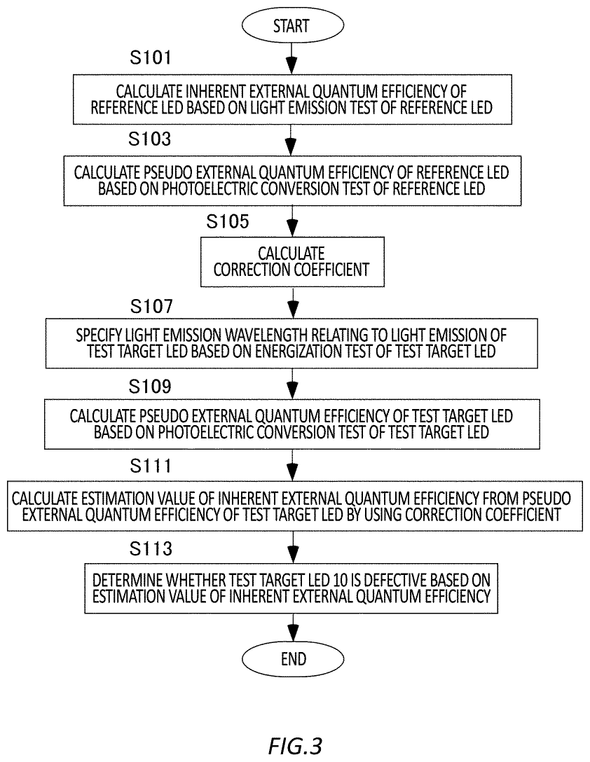

FIG. 3 is an example of a flow diagram for explaining a flow of a testing method by the testing apparatus 100. The operation flow shown in FIG. 3 is started when, for example, a user provides input to the testing apparatus 100 to start a test of the LED group in a state where the LED group is placed on the placement unit 110.

The testing apparatus 100 calculates the inherent external quantum efficiency of the reference LED 10 based on the light emission test of the reference LED 10 (step S101). More specifically, in a state where one or more reference LEDs 10 are placed on the placement unit 110, the light emission control unit 160 of the testing apparatus 100 supplies current of a predetermined magnitude to the one or more reference LEDs 10 via the electrical connection unit 120, thereby causing those LEDs 10 to emit light. The light measurement unit 170 receives the light emitted from the one or more reference LEDs 10 via the optical system 140, measures the wavelength and light emission intensity of the received light, and outputs a measurement result to the calculation unit 180. The wavelength of the light may be, for example, the center wavelength of the combined light emitted from the plurality of reference LEDs 10.

The calculation unit 180 calculates the inherent external quantum efficiency of the reference LED 10, based on the measured wavelength and light emission intensity of the reference LED 10 and the current input to the reference LED 10 by the light emission control unit 160. As an example, the calculation unit 180 calculates the inherent external quantum efficiency of the reference LED 10 with reference to the derivation formula of the inherent external quantum efficiency stored in the storage unit 200.

The testing apparatus 100 calculates the pseudo external quantum efficiency of the reference LED 10 based on the photoelectric conversion test of the reference LED 10 (step S103).

More specifically, the light source 130 of the testing apparatus 100 irradiates one or more reference LEDs 10 with light at predetermined irradiation intensity via the optical system 140. The electrical measurement unit 150 measures, via the electrical connection unit 120, a photoelectric signal obtained by photoelectrically converting light radiated from each of the one or more reference LEDs 10, and outputs a measurement result to the calculation unit 180. The calculation unit 180 calculates the pseudo external quantum efficiency of each of the one or more reference LEDs 10, based on the irradiation intensity of the light radiated from the light source 130 to the one or more reference LEDs 10, the wavelength of the one or more reference LEDs 10 measured in step S101 as the light emission wavelength relating to the light emission of the test target LED 10, and the measured photoelectric signal of each of the one or more reference LEDs 10.

The testing apparatus 100 calculates the above-described correction coefficient (step S105). More specifically, the calculation unit 180 of the testing apparatus 100 calculates the correction coefficient by dividing the pseudo external quantum efficiency of each of the one or more reference LEDs 10 by the inherent external quantum efficiency of the one or more reference LEDs 10. When a plurality of reference LEDs 10 are used, the calculation unit 180 may derive an average value of correction coefficients for the number of LEDs 10 calculated based on the individual pseudo external quantum efficiency of each LED 10 and the inherent external quantum efficiency common to all the LEDs 10, or may select a median value of the plurality of correction coefficients.

The testing apparatus 100 specifies the light emission wavelength relating to the light emission of the test target LED 10, based on the energization test of the test target LED 10 (step S107). More specifically, in a state where a plurality of test target LEDs 10 are placed on the placement unit 110, the light emission control unit 160 of the testing apparatus 100 supplies current of a predetermined magnitude to the plurality of test target LEDs 10 via the electrical connection unit 120, thereby causing these LEDs 10 to emit light. The light measurement unit 170 receives the combined light emitted from the plurality of test target LEDs 10 via the optical system 140, measures the wavelength of the received combined light, and outputs a measurement result to the calculation unit 180. The calculation unit 180 specifies the wavelength of the combined light emitted from the plurality of test target LEDs 10 as the light emission wavelength relating to the light emission of the plurality of test target LEDs 10. The wavelength of the combined light may be, for example, the center wavelength of the combined light.

The testing apparatus 100 calculates the pseudo external quantum efficiency of the test target LED 10 based on the photoelectric conversion test of the test target LED 10 (step S109). More specifically, the light source 130 of the testing apparatus 100 irradiates a plurality of test target LEDs 10 with light at the irradiation intensity set in step S103 via the optical system 140. The electrical measurement unit 150 measures, via the electrical connection unit 120, a photoelectric signal obtained by photoelectrically converting light radiated from each of the plurality of test target LEDs 10, and outputs a measurement result to the calculation unit 180. The calculation unit 180 calculates the pseudo external quantum efficiency of each of the plurality of test target LEDs 10, based on the irradiation intensity of the light radiated from the light source 130 to the plurality of test target LEDs 10, the wavelength of the plurality of test target LEDs 10 measured in step S107 as the light emission wavelength relating to the light emission of the test target LED 10, and the measured photoelectric signal of each of the plurality of test target LEDs 10.

The testing apparatus 100 calculates the estimation value of the inherent external quantum efficiency from the pseudo external quantum efficiency of the test target LED 10 by using the correction coefficient (step S111). More specifically, the calculation unit 180 of the testing apparatus 100 uses the correction coefficient calculated in step S105 to calculate the estimation value of the inherent external quantum efficiency of each of the plurality of test target LEDs 10 from the pseudo external quantum efficiency of each of the plurality of test target LEDs 10. As an example, the calculation unit 180 calculates the inherent external quantum efficiency of each LED 10 by dividing the pseudo external quantum efficiency of each LED 10 by the correction coefficient. The calculation unit 180 outputs a calculation result to the determination unit 190.

The testing apparatus 100 determines whether the test target LED 10 is defective based on the estimation value of the inherent external quantum efficiency (step S113), and the flow ends. More specifically, as an example, the determination unit 190 of the testing apparatus 100 compares the inherent external quantum efficiency of each LED 10 input from the calculation unit 180 with the threshold stored in the storage unit 200, determines the LED 10, which has inherent external quantum efficiency less than the threshold, as defective, and excludes the LED 10 from the targets of the subsequent test.

In the testing apparatus 100, the order of each step in the operation flow of FIG. 3 may be different, and one or more steps may be omitted. For example, in the operation flow of FIG. 3, the order of step S101 and step S103 may be reversed. In addition, steps S101 to S107 may be omitted, and in this case, the testing apparatus 100 may acquire in advance the correction coefficient calculated in step S105 and the light emission wavelength relating to the light emission of the test target LED 10 measured in step S107, and store the acquired correction coefficient and light emission wavelength in the storage unit 200. In addition, the irradiation intensity of the light source 130 in steps S103 and S109 may be measured in advance or may be a set value input to the light source 130.

As described above, according to the testing apparatus 100 of the present embodiment, the test target LED 10 is irradiated with the light emitted from the light source 130, the photoelectric signal obtained by photoelectrically converting the light radiated by the test target LED 10 is measured, and the pseudo external quantum efficiency having the correlation with the inherent external quantum efficiency of the test target LED 10 is calculated based on the irradiation intensity of the light radiated from the light source 130 to the test target LED 10, the light emission wavelength relating to the light emission of the test target LED 10, and the measured photoelectric signal of the test target LED 10.

As a comparative example with the testing apparatus 100 according to the present embodiment, an apparatus is assumed which calculates inherent external quantum efficiency by measuring a wavelength and light emission intensity of light emitted by applying current of a predetermined magnitude to a test target light emitting element. For example, in a semiconductor test, a large number of light emitting elements are arranged adjacent to one another, and in a case where the semiconductor test is performed by using the apparatus, when a large number of light emitting elements are caused to collectively emit light, the light of the adjacent light emitting elements is mixed, so that the light emission intensity of each light emitting element cannot be accurately measured. In the apparatus, when a large number of light emitting elements are caused to sequentially emit light in order to avoid this, it takes a lot of processing time to measure the light emission intensity of all the light emitting elements and calculate the inherent external quantum efficiency.

On the other hand, according to the testing apparatus 100 according to the present embodiment, the pseudo external quantum efficiency is calculated by measuring the photoelectric signal output by irradiating the test target light emitting element with light having irradiation intensity of a predetermined magnitude. Even when testing a semiconductor in which a large number of light emitting elements are arranged adjacent to one another, the testing apparatus 100 can simultaneously measure the photoelectric signal of each light emitting element by collectively irradiating the large number of light emitting elements with light, and calculate the pseudo external quantum efficiency of each light emitting element in parallel in time. Therefore, by using the correction coefficient calculated in advance for the test target light emitting element, the testing apparatus 100 can also calculate an estimation value of inherent external quantum efficiency, which has a correlation with the pseudo external quantum efficiency of each light emitting element, in parallel in time. Accordingly, the testing apparatus 100 can greatly shorten a processing time until the estimation value of the inherent external quantum efficiency of each light emitting element is calculated, that is, the execution time of the test, compared with the apparatus of the above-described comparative example. Note that the testing apparatus 100 can also evaluate the light emission characteristics of each light emitting element based on the pseudo external quantum efficiency of each light emitting element.

In the plurality of embodiments described above, the light measurement unit 170 of the testing apparatus 100 has been described as a configuration in which the wavelength of the combined light obtained by combining the light emitted from each of the plurality of test target LEDs 10 and the wavelength of the light emitted from the reference LED 10 are measured as the light emission wavelength relating to the light emission of the plurality of test target LEDs 10. Further, the calculation unit 180 of the testing apparatus 100 has been described as a configuration in which the pseudo external quantum efficiency of each of the plurality of test target LEDs 10 is calculated by using the photoelectric signal of each of the plurality of test target LEDs 10 measured by the electrical measurement unit 150 and the wavelength of the combined light measured by the light measurement unit 170 or the wavelength of the reference LED 10.

Alternatively, the light measurement unit 170 of the testing apparatus 100 may not measure at least one of the wavelength of the combined light obtained by combining the light emitted from each of the plurality of test target LEDs 10 or the wavelength of the reference LED 10. Alternatively, the testing apparatus 100 may not include the light measurement unit 170, and in this case, the optical system 140 may not include the bifurcated fiber 141. When the testing apparatus 100 does not measure the wavelength of the combined light of the plurality of test target LEDs 10 and the wavelength of the reference LED 10, the testing apparatus 100 may use a wavelength conforming to the design value of the reference LED 10, a wavelength measured in advance by the light emission test of the reference LED 10, or a wavelength conforming to the design value of one or more test target LEDs 10 as the light emission wavelength relating to the light emission of the one or more test target LEDs 10. Before calculating the pseudo external quantum efficiency of the test target LED 10, the testing apparatus 100 may acquire data of these wavelengths, for example, from the outside of the testing apparatus 100 by a user input and store the data in the storage unit 200. In this case, the calculation unit 180 of the testing apparatus 100 further calculates the pseudo external quantum efficiency of each of the one or more test target LEDs 10 by using the photoelectric signal of each of the one or more test target LEDs 10 measured by the electrical measurement unit 150 and the wavelength thereof.

In the plurality of embodiments described above, the light measurement unit 170 of the testing apparatus 100 has been described as a configuration in which the wavelength and the light emission intensity of the light emitted from the reference LED 10 are measured for the calculation of the correction coefficient by the calculation unit 180. Further, the calculation unit 180 of the testing apparatus 100 has been described as a configuration in which the pseudo external quantum efficiency of the reference LED 10 is calculated by using the photoelectric signal of the reference LED 10 measured by the electrical measurement unit 150 and the wavelength of the reference LED 10 measured by the light measurement unit 170. The calculation unit 180 has been further described as a configuration in which the inherent external quantum efficiency of the reference LED 10 is calculated based on the wavelength and the light emission intensity of the reference LED 10 measured by the light measurement unit 170 and the current input to the reference LED 10 by the light emission control unit 160. The calculation unit 180 has been further described as a configuration in which the correction coefficient is calculated by dividing the pseudo external quantum efficiency of the reference LED 10 by the inherent external quantum efficiency of the reference LED 10.

Alternatively, the light measurement unit 170 of the testing apparatus 100 may not measure the wavelength of the light emitted from the reference LED 10, and the calculation unit 180 may acquire the correction coefficient corresponding to the test target LED 10, for example, from the outside of the testing apparatus 100 by a user input and store the correction coefficient in the storage unit 200 before calculating the estimation value of the inherent external quantum efficiency of the test target LED 10. In this case, the calculation unit 180 of the testing apparatus 100 further calculates the estimation value of the inherent external quantum efficiency of the test target LED 10 from the pseudo external quantum efficiency calculated for the test target LED 10 by using the correction coefficient acquired from the outside.

In the plurality of embodiments described above, instead of the branched fiber such as the bifurcated fiber 141, the testing apparatus 100 may include another mechanism such as a prism in the optical system 140. In this case, the prism or the like has a functional configuration similar to the functional configuration of the bifurcated fiber 141 described in the above embodiment.

In the plurality of embodiments described above, when the LED group has a configuration in which the plurality of LEDs are formed on a glass-based panel (PLP) having a substantially rectangular outer shape on which electrical wirings are formed, the electrical connection unit may have a configuration in which the probe is brought into contact with each wiring in a row direction and a column direction arranged on two side surfaces of the panel.

Various embodiments of the present invention may be described with reference to flowcharts and block diagrams whose blocks may represent (1) steps of processes in which operations are performed or (2) sections of apparatuses responsible for performing operations. Certain steps and sections may be implemented by dedicated circuitry, programmable circuitry supplied with computer-readable instructions stored on computer-readable media, and/or processors supplied with computer-readable instructions stored on computer-readable media.

Dedicated circuitry may include digital and/or analog hardware circuits, and may include integrated circuits (IC) and/or discrete circuits. The programmable circuitry may include a reconfigurable hardware circuit including logical AND, logical OR, logical XOR, logical NAND, logical NOR, and other logical operations, a memory element such as a flip-flop, a register, a field programmable gate array (FPGA) and a programmable logic array (PLA), and the like.

A computer-readable medium may include any tangible device that can store instructions to be executed by a suitable device, and as a result, the computer-readable medium having instructions stored thereon includes an article of manufacture including instructions which can be executed in order to create means for performing operations specified in the flowcharts or block diagrams. Examples of the computer readable medium may include an electronic storage medium, a magnetic storage medium, an optical storage medium, an electromagnetic storage medium, a semiconductor storage medium, and the like. More specific examples of the computer readable medium may include a floppy (registered trademark) disk, a diskette, a hard disk, a random access memory (RAM), a read-only memory (ROM), an erasable programmable read-only memory (EPROM or flash memory), an electrically erasable programmable read-only memory (EEPROM), a static random access memory (SRAM), a compact disc read-only memory (CD-ROM), a digital versatile disk (DVD), a Blu-ray (registered trademark) disk, a memory stick, an integrated circuit card, or the like.

The computer-readable instruction may include: an assembler instruction, an instruction-set-architecture (ISA) instruction; a machine instruction; a machine dependent instruction; a microcode; a firmware instruction; state-setting data; or either a source code or an object code written in any combination of one or more programming languages, including an object oriented programming language such as Smalltalk (registered trademark), JAVA (registered trademark), C++, or the like, and a conventional procedural programming language such as a “C” programming language or a similar programming language.

The computer-readable instruction may be provided for a processor or programmable circuitry of a programmable data processing apparatus, such as a computer, locally or via a local area network (LAN), a wide area network (WAN) such as the Internet, or the like to execute the computer-readable instruction in order to create means for executing the operations specified in the flowcharts or block diagrams. Here, the computer may be a personal computer (PC), a tablet computer, a smart phone, a workstation, a server computer, or a computer such as a general purpose computer or a special purpose computer, or may be a computer system to which a plurality of computers are connected. Such computer system to which the plurality of computers are connected is also referred to as a distributed computing system, and is a computer in a broad sense. In a distributed computing system, a plurality of computers collectively execute a program by each of the plurality of computers executing a portion of the program, and passing data during the execution of the program among the computers as needed.

Examples of the processor include a computer processor, a central processing unit (CPU), a processing unit, a microprocessor, a digital signal processor, a controller, and a microcontroller. The computer may include one processor or a plurality of processors. In a multi-processor system including a plurality of processors, the plurality of processors collectively execute a program by each of the processors executing a portion of the program, and passing data during the execution of the program among the computers as needed. For example, in execution of multiple tasks, each of the plurality of processors may execute a portion of each task pieces by pieces by performing task-switching for each time slice. In this case, which portion of one program each processor is responsible for executing dynamically changes. Moreover, which portion of the program each of the plurality of processor is responsible for executing may be determined statically by multiprocessor-aware programming.

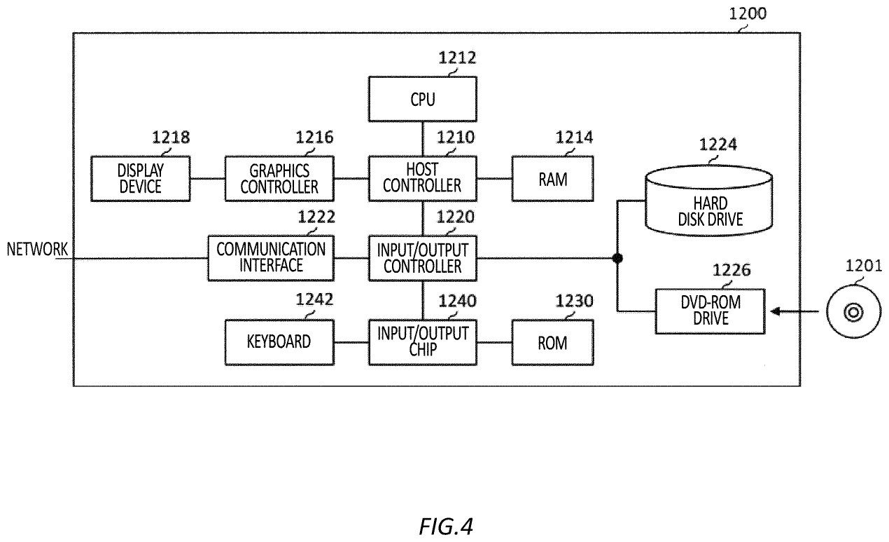

FIG. 4 shows an example of a computer 1200 in which a plurality of aspects of the present invention may be embodied in whole or in part. A program that is installed in the computer 1200 can cause the computer 1200 to function as one or more “sections” in an operation or an apparatus associated with the embodiment of the present invention, or cause the computer 1200 to perform the operation or the one or more sections thereof, and/or cause the computer 1200 to perform processes of the embodiment of the present invention or steps thereof. Such a program may be performed by a CPU 1212 so as to cause the computer 1200 to perform certain operations associated with some or all of the blocks of flowcharts and block diagrams described herein.

The computer 1200 in accordance with the present embodiment includes a CPU 1212, a RAM 1214, a graphics controller 1216, and a display device 1218, which are mutually connected by a host controller 1210. The computer 1200 also includes input/output units such as a communication interface 1222, a hard disk drive 1224, a DVD-ROM drive 1226, and an IC card drive, which are connected to the host controller 1210 via an input/output controller 1220. The computer also includes legacy input/output units such as an ROM 1230 and a keyboard 1242, which are connected to the input/output controller 1220 via an input/output chip 1240.

The CPU 1212 operates according to programs stored in the ROM 1230 and the RAM 1214, thereby controlling each unit. The graphics controller 1216 obtains image data generated by the CPU 1212 on a frame buffer or the like provided in the RAM 1214 or in itself, and causes the image data to be displayed on a display device 1218.

The communication interface 1222 communicates with other electronic devices via a network. The hard disk drive 1224 stores programs and data that are used by the CPU 1212 within the computer 1200. The DVD-ROM drive 1226 reads a program or data from a DVD-ROM 1201 and provides the program or data to the hard disk drive 1224 via the RAM 1214. The IC card drive reads programs and data from an IC card, and/or writes programs and data to the IC card.

The ROM 1230 stores therein a boot program or the like that is performed by the computer 1200 at the time of activation, and/or a program depending on the hardware of the computer 1200. The input/output chip 1240 may also connect various input/output units to the input/output controller 1220 via a parallel port, a serial port, a keyboard port, a mouse port, or the like.

A program is provided by computer readable media such as the DVD-ROM 1201 or the IC card. The program is read from the computer readable media, installed into the hard disk drive 1224, RAM 1214, or ROM 1230, which are also examples of computer readable media, and performed by the CPU 1212. Information processing written in these programs is read by the computer 1200, and provides cooperation between the programs and the various types of hardware resources described above. An apparatus or method may be constituted by realizing the operation or processing of information in accordance with the usage of the computer 1200.

For example, when communication is performed between the computer 1200 and an external device, the CPU 1212 may perform a communication program loaded onto the RAM 1214 to instruct communication processing to the communication interface 1222, based on the processing described in the communication program. The communication interface 1222, under control of the CPU 1212, reads transmission data stored on a transmission buffer processing region provided in a recording medium such as the RAM 1214, the hard disk drive 1224, the DVD-ROM 1201, or the IC card, and transmits the read transmission data to a network or writes reception data received from the network to a reception buffer processing region or the like provided on the recording medium.

The CPU 1212 may be configured to cause all or a necessary portion of a file or a database, which has been stored in an external recording medium such as the hard disk drive 1224, the DVD-ROM drive 1226 (DVD-ROM 1201), and the IC card, to be read into the RAM 1214, thereby executing various types of processing on the data on the RAM 1214. The CPU 1212 may then write back the processed data to the external recording medium.

Various types of information such as various types of programs, data, tables, and databases may be stored in a recording medium and subjected to information processing. The CPU 1212 may perform various types of processing on the data read from the RAM 1214, which includes various types of operations, processing of information, condition judging, conditional branch, unconditional branch, search/replace of information, etc., as described throughout this disclosure and designated by an instruction sequence of programs, and writes the result back to the RAM 1214. In addition, the CPU 1212 may retrieve information in a file, a database, or the like in the recording medium. For example, when a plurality of entries each having an attribute value of a first attribute associated with an attribute value of a second attribute are stored in the recording medium, the CPU 1212 may retrieve, out of the plurality of entries, an entry with the attribute value of the first attribute specified that meets a condition, read the attribute value of the second attribute stored in the entry, and thereby acquire the attribute value of the second attribute associated with the first attribute meeting a predetermined condition.

The above-explained program or software modules may be stored in the computer readable media on or near the computer 1200. In addition, a recording medium such as a hard disk or a RAM provided in a server system connected to a dedicated communication network or the Internet can be used as the computer readable media, thereby providing the program to the computer 1200 via the network.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from description of the claims that the embodiments to which such alterations or improvements are made can be included in the technical scope of the present invention.

It should be noted that the operations, procedures, steps, stages, and the like of each process performed by an apparatus, system, program, and method shown in the claims, embodiments, or diagrams can be realized in any order as long as the order is not indicated by “prior to,” “before,” or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10: LED

11: terminal

15: wafer

100: testing apparatus

110: placement unit

111: through hole

120: electrical connection unit

121: substrate

123: probe

130: light source

140: optical system

150: electrical measurement unit

160: light emission control unit

170: light measurement unit

180: calculation unit

190: determination unit

200: storage unit

210: shielding unit

1200: computer

1201: DVD-ROM

1210: host controller

1212: CPU

1214: RAM

1216: graphics controller

1218: display device

1220: input/output controller

1222: communication interface

1224 hard disk drive

1226 DVD-ROM drive

1230: ROM

1240: input/output chip

1242: keyboard

What is claimed is:

1. A testing apparatus comprising:
a light source;
an electrical measurement unit which measures a photoelectric signal obtained by a test target light emitting element photoelectrically converting light radiated from the light source; and
a calculation unit which calculates pseudo external quantum efficiency having a correlation with inherent external quantum efficiency of the test target light emitting element, based on irradiation intensity of light radiated from the light source to the test target light emitting element, a light emission wavelength relating to light emission of the test target light emitting element, and the photoelectric signal being measured of the test target light emitting element.

2. The testing apparatus according to claim 1, wherein
the calculation unit calculates an estimation value of inherent external quantum efficiency, which is obtained from a light emission test, of the test target light emitting element from the pseudo external quantum efficiency of the test target light emitting element by using a correction coefficient based on the pseudo external quantum efficiency calculated in advance for a reference light emitting element and inherent external quantum efficiency calculated in advance for a light emission test of the reference light emitting element.

3. The testing apparatus according to claim 2, wherein
the reference light emitting element is an ideal light emitting element conforming to a design value of the test target light emitting element, or is a light emitting element that is included in a same production lot as the test target light emitting element and satisfies a predetermined acceptance reference.

4. The testing apparatus according to claim 2, wherein
the light emission wavelength relating to light emission of the test target light emitting element is a wavelength conforming to a design value of the reference light emitting element, a wavelength measured in advance by the light emission test of the reference light emitting element, or a wavelength conforming to a design value of the test target light emitting element.

5. The testing apparatus according to claim 2, further comprising:
a light emission control unit which causes the reference light emitting element to emit light; and
a light measurement unit which measures a wavelength and light emission intensity of light emitted from the reference light emitting element, wherein the calculation unit
calculates the pseudo external quantum efficiency of the reference light emitting element based on the irradiation intensity of light radiated from the light source to the reference light emitting element, the wavelength of the reference light emitting element measured as the light emission wavelength relating to light emission of the test target light emitting element, and the photoelectric signal being measured of the reference light emitting element,
calculates the inherent external quantum efficiency of the reference light emitting element based on the wavelength and the light emission intensity being measured of the reference light emitting element and current input to the reference light emitting element by the light emission control unit, and
calculates the correction coefficient by dividing the pseudo external quantum efficiency by the inherent external quantum efficiency.

6. The testing apparatus according to claim 5, further comprising
an optical system which irradiates the reference light emitting element with light incident from the light source in one direction, and irradiates the light measurement unit with light incident from the reference light emitting element in another direction.

7. The testing apparatus according to claim 1, wherein
the electrical measurement unit measures the photoelectric signal obtained by each of a plurality of test target light emitting elements photoelectrically converting light collectively radiated from the light source, and
the calculation unit calculates the pseudo external quantum efficiency of each of the plurality of test target light emitting elements based on the irradiation intensity of light radiated from the light source to the plurality of test target light emitting elements, the light emission wavelength relating to light emission of the plurality of test target light emitting elements, and the photoelectric signal measured for each of the plurality of test target light emitting elements.

8. The testing apparatus according to claim 2, wherein
the electrical measurement unit measures the photoelectric signal obtained by each of a plurality of test target light emitting elements photoelectrically converting light collectively radiated from the light source, and
the calculation unit calculates the pseudo external quantum efficiency of each of the plurality of test target light emitting elements based on the irradiation intensity of light radiated from the light source to the plurality of test target light emitting elements, the light emission wavelength relating to light emission of the plurality of test target light emitting elements, and the photoelectric signal measured for each of the plurality of test target light emitting elements.

9. The testing apparatus according to claim 3, wherein
the electrical measurement unit measures the photoelectric signal obtained by each of a plurality of test target light emitting elements photoelectrically converting light collectively radiated from the light source, and
the calculation unit calculates the pseudo external quantum efficiency of each of the plurality of test target light emitting elements based on the irradiation intensity of light radiated from the light source to the plurality of test target light emitting elements, the light emission wavelength relating to light emission of the plurality of test target light emitting elements, and the photoelectric signal measured for each of the plurality of test target light emitting elements.

10. The testing apparatus according to claim 4, wherein
the electrical measurement unit measures the photoelectric signal obtained by each of a plurality of test target light emitting elements photoelectrically converting light collectively radiated from the light source, and
the calculation unit calculates the pseudo external quantum efficiency of each of the plurality of test target light emitting elements based on the irradiation intensity of light radiated from the light source to the plurality of test target light emitting elements, the light emission wavelength relating to light emission of the plurality of test target light emitting elements, and the photoelectric signal measured for each of the plurality of test target light emitting elements.

11. The testing apparatus according to claim 5, wherein
the electrical measurement unit measures the photoelectric signal obtained by each of a plurality of test target light emitting elements photoelectrically converting light collectively radiated from the light source, and
the calculation unit calculates the pseudo external quantum efficiency of each of the plurality of test target light emitting elements based on the irradiation intensity of light radiated from the light source to the plurality of test target light emitting elements, the light emission wavelength relating to light emission of the plurality of test target light emitting elements, and the photoelectric signal measured for each of the plurality of test target light emitting elements.

12. The testing apparatus according to claim 6, wherein
the electrical measurement unit measures the photoelectric signal obtained by each of a plurality of test target light emitting elements photoelectrically converting light collectively radiated from the light source, and
the calculation unit calculates the pseudo external quantum efficiency of each of the plurality of test target light emitting elements based on the irradiation intensity of light radiated from the light source to the plurality of test target light emitting elements, the light emission wavelength relating to light emission of the plurality of test target light emitting elements, and the photoelectric signal measured for each of the plurality of test target light emitting elements.

13. The testing apparatus according to claim 7, wherein
the calculation unit calculates an estimation value of inherent external quantum efficiency, which is obtained from a light emission test, of each of the plurality of test target light emitting elements from the pseudo external quantum efficiency of each of the plurality of test target light emitting elements by using a correction coefficient based on the pseudo external quantum efficiency calculated in advance for a reference light emitting element and inherent external quantum efficiency calculated in advance for a light emission test of the reference light emitting element.

14. The testing apparatus according to claim 8, wherein
the calculation unit calculates an estimation value of inherent external quantum efficiency, which is obtained from a light emission test, of each of the plurality of test target light emitting elements from the pseudo external quantum efficiency of each of the plurality of test target light emitting elements by using a correction coefficient based on the pseudo external quantum efficiency calculated in advance for a reference light emitting element and inherent external quantum efficiency calculated in advance for a light emission test of the reference light emitting element.

15. The testing apparatus according to claim 9, wherein
the calculation unit calculates an estimation value of inherent external quantum efficiency, which is obtained from a light emission test, of each of the plurality of test target light emitting elements from the pseudo external quantum efficiency of each of the plurality of test target light emitting elements by using a correction coefficient based on the pseudo external quantum efficiency calculated in advance for a reference light emitting element and inherent external quantum efficiency calculated in advance for a light emission test of the reference light emitting element.

16. The testing apparatus according to claim 13, wherein the calculation unit uses the correction coefficient varying depending on a production lot including the plurality of test target light emitting elements.

17. The testing apparatus according to claim 13, further comprising a determination unit which determines quality of each of the plurality of test target light emitting elements based on the estimation value of the inherent external quantum efficiency of each of the plurality of test target light emitting elements.

18. The testing apparatus according to claim 7, further comprising:
a light emission control unit which causes the plurality of test target light emitting elements to collectively emit light;
a light measurement unit which measures, as the light emission wavelength relating to light emission of the plurality of test target light emitting elements, a wavelength of combined light obtained by combining light emitted from each of the plurality of test target light emitting elements; and
an optical system which irradiates the plurality of test target light emitting elements with light incident from the light source in one direction, and irradiates the light measurement unit with combined light obtained by combining light incident from each of the plurality of test target light emitting elements in another direction.

19. A testing method comprising:
irradiating a test target light emitting element with light emitted from a light source;
measuring a photoelectric signal obtained by the test target light emitting element photoelectrically converting radiated light; and
calculating pseudo external quantum efficiency having a correlation with inherent external quantum efficiency of the test target light emitting element, based on irradiation intensity of light radiated from the light source to the test target light emitting element, a light emission wavelength relating to light emission of the test target light emitting element, and the photoelectric signal being measured of the test target light emitting element.

20. A computer-readable storage medium having stored therein a program for causing a testing apparatus, which tests a light emitting element, to execute:
irradiating a test target light emitting element with light emitted from a light source;
measuring a photoelectric signal obtained by the test target light emitting element photoelectrically converting radiated light; and
calculating pseudo external quantum efficiency having a correlation with inherent external quantum efficiency of the test target light emitting element, based on irradiation intensity of light radiated from the light source to the test target light emitting element, a light emission wavelength relating to light emission of the test target light emitting element, and the photoelectric signal being measured of the test target light emitting element.
